(19) United States
(12) Patent Application Publication
(10) Pub. No.: US 2012/0103392 A1
(43) Pub. Date: May 3, 2012

(54) STRETCHABLE PHOTOVOLTAIC MODULES ON WAVY SUBSTRATES

(75) Inventor: Jurgen H. Daniel, San Francisco, CA (US)

(73) Assignee: PALO ALTO RESEARCH CENTER INCORPORATED, Palo Alto, CA (US)

(21) Appl. No.: 12/916,288

(22) Filed: Oct. 29, 2010

(51) Int. Cl. H01L 31/042; H01L 31/048; H01L 31/18; H01L 31/045

(52) U.S. Cl. 136/246; 136/244; 136/251; 438/65; 257/E31.127

(57) ABSTRACT

An electronics module has a wavy substrate having ridges and creases, and an array of functional components on the substrate, the functional components including solar components and arranged on the substrate so at least one of the components lies between the creases. A method of manufacturing an electronics module includes providing functional components, at least one of the functional components being a portion of a solar cell, mounting the functional components on a flexible substrate, and forming creases and ridges in the flexible substrate, such that the functional components are arranged to reside between the creases.

### BACKGROUND

Renewable energy resources, such as wind and solar, have become much more popular as people seek alternative energy sources. With the rise in demand, solar products have undergone considerable changes from the traditional, large area solar panels in rigid frames. Solar panels have become smaller, lighter and much more modular.

Some photovoltaic modules now reside on flexible, bendable substrates. Manufacturers that produce flexible solar modules include Unisolar, Global Solar and Konarka. These flexible solar substrates generally consist of thin, stainless steel foil or thin, polymer foil. In addition to photovoltaic modules, these substrates may also include sensors or other electronic modules and circuits. While these substrates have more flexibility and are more bendable than previous substrates, there is still room for improvement.

Some efforts have concentrated on bending more traditional substrates by selectively cutting or notching the substrates to allow them to conform to more three-dimensional shapes. Examples of this approach include U.S. patent application Ser. No. 12/017,974, published as US Patent Publication No. 20090184954; and Ser. No. 12/253,390, Published as 20100096729. In the approach discussed in these publications, an electronics circuit and its components are laid out on a flexible circuit substrate. The process then cuts the flexible circuit substrate to allow it to be bent, shaped or molded into a three-dimensional device.

Similarly, U.S. patent application Ser. No. 12/563,945, “Shaped Active Matrix Displays,” discusses a combination of the cutting for shaping and the lay out of the circuits to allow for holes to be formed in the substrate, or for the substrate to take a particular shape, such as that of an alphabetic character.

The approach taken in these references, however, involves cutting or perforating the substrate for flexibility and shaping, it does not address stretchability.

### BRIEF DESCRIPTION OF THE DRAWINGS

FIG. 1 shows an embodiment of an electronics module having functional components arrayed on a flexible substrate in a stretched position.

FIG. 2 shows an embodiment of an electronics module having functional components arrayed on a flexible substrate in a relaxed position, the substrate having ridges and creases.

FIG. 3 shows an embodiment of a substrate having ridges oriented in different directions.

FIG. 4 shows an embodiment of a flexible, wavy substrate having stepped creases.

FIG. 5 shows an embodiment of a flexible, wavy substrate having sinusoidal creases.

FIGS. 6-8 show alternative embodiments of a wavy substrate having elastic lenses.

FIG. 9 shows an embodiment of a wavy substrate having functional components of different sizes and positions.

FIG. 10 shows an embodiment of a wavy substrate having functional components of different sizes and having elastic lenses.

FIGS. 11-12 show embodiments of a wavy substrate having an encapsulant layer.

### DETAILED DESCRIPTION OF THE EMBODIMENTS

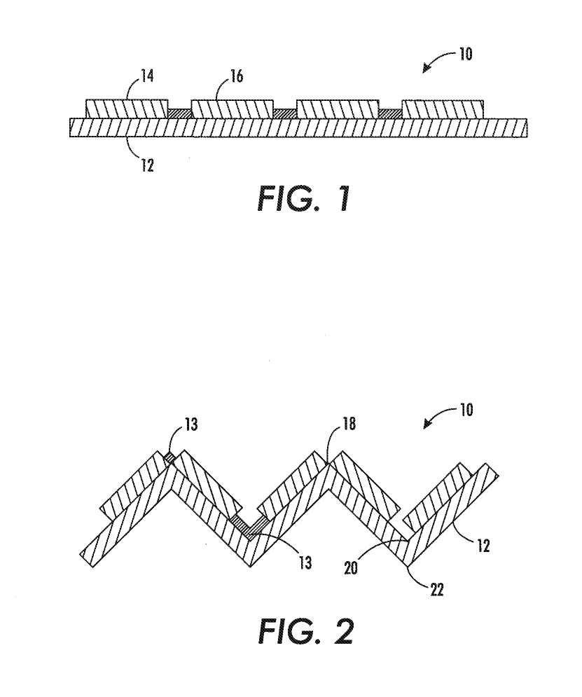

FIG. 1 shows an embodiment of an electronics module formed from a flexible, wavy substrate. The flexible, wavy substrate may consist of many types of materials, including stretch fabric, polymers and elastomers. The substrate may be pre-formed, such as one pressed or formed into a wavy shape, possibly by using a roll-to-roll process. A wavy substrate, or substrate with ridges and creases may be manufactured by folding a foil-like material repeatedly or it may be formed by vacuum forming of a foil in which a polymer foil is pressed by the force of a vacuum against a metal structure with ridges and valleys. Other manufacturing methods to form a substrate with waves, such as embossing, are known in the art. Substrate materials include thin metal foil, polymer foil, paper, and woven or non-woven fabric. In one example, the substrate is made from polymer foil such as Mylar, polyester, polycarbonate, polyimide foil. Alternatively, the substrate may just be a flexible material that naturally has rolls or waves in its structure due to its own elasticity.

In FIG. 1, the substrate 12 of the electronics module 10 is stretched or otherwise flattened. This allows the attachment of individual functional components, such as a solar tile 14 or a sensor 16. Many types of functional components may reside on the substrate including mirrors, light emitters, light scattering components, and sensors. In particular, the functional components may include components with electronic functionality. In the case of solar tiles, these will generally consist of smaller portions of solar cells, diced into smaller tiles or ‘flakes’ allowing them to reside on wavy substrates. For example, the tiles may consist of strips or slivers cut or otherwise separated from a larger solar cell. The tiles may also consist of squares or rectangular chips cut from a larger solar cell. In particular, the solar cell may be a back contact solar cell and the tiles may be attached to the substrate by a bonding method similar to flip-chip bonding. A pick and place method may be employed to attach the tiles or functional components to the substrate.

In FIG. 2, the substrate 12 has been released from its stretched shape, taking on its relaxed or wavy state. In the case of a ‘naturally’ wavy substrate, the presence of the functional components will generally cause the substrate 12 to have ridges such as 18 between the components on some portions of the substrate and creases, such as 20, on the other portions of the substrate. These ridges and creases may take different forms. In the embodiment of FIG. 2, the substrate has taken on a ‘waved’ form, with the ridges as peaks and the creases as troughs. The tiles or functional components in FIG. 1, FIG. 2 or any embodiment may be interconnected using flexible or traditional conductive paths 13, with the interconnections arranged so as to minimize any shading loss on the surfaces of the solar tiles.

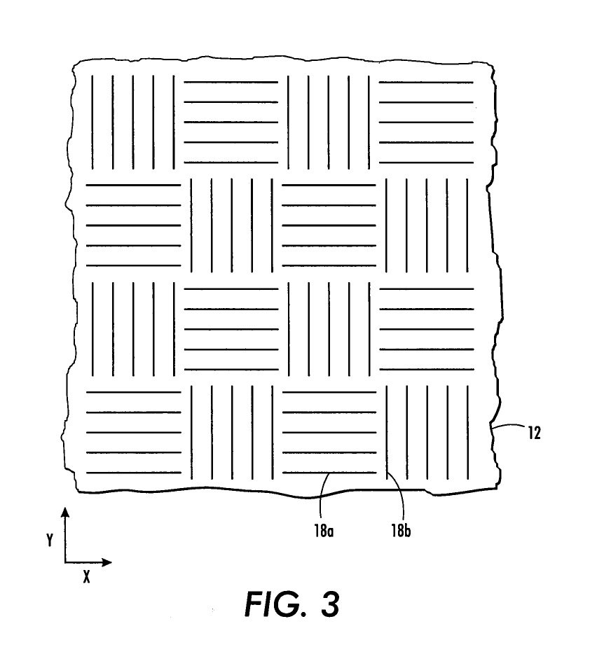

The ridges may have different orientations across the substrate to allow it to stretch in multiple dimensions. For example, in FIG. 3, the substrate has sets of ridges such as 18a formed oriented in an ‘X’ direction, allowing the substrate to stretch in a ‘Y’ direction. Other sets of ridges such as 18b follow a ‘Y’ direction orientation, allowing the substrate to stretch in the ‘X’ direction. These groups of ridges may be formed by pressing, stamping or molding the substrate, as mentioned previously.

The term ‘ridge’ as used here designates a region or regions of the substrate that extend above a plane in which the substrate is flat. For example, looking at FIG. 1, the substrate resides in a plane referred to here as the ‘flat’ plane. In FIG. 2, the ridge 18 resides above the flat plane, while the bottom surface such as 22 of a crease such as 22 remains in the flat plane. The term ‘crease’ then designates a region of the substrate that remains in the flat plane.

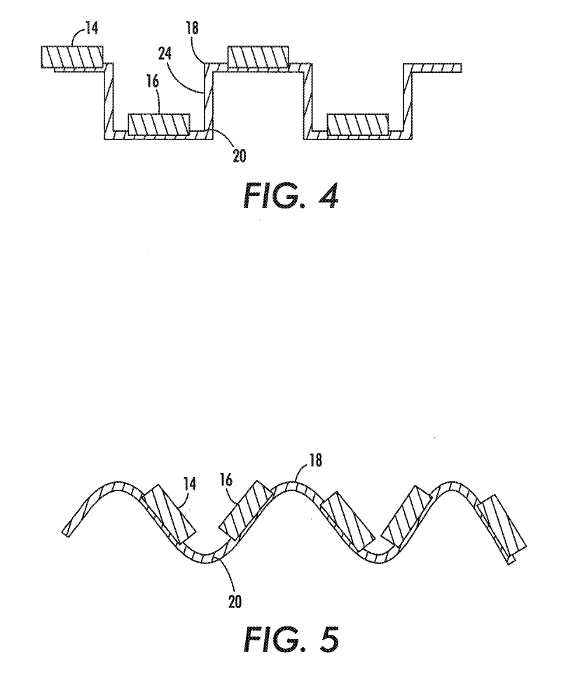

FIGS. 4 and 5 show alternative embodiments of the substrate in its wavy form. In FIG. 4 the ridges and creases have a larger horizontal extent than those in the wave form of FIG. 2. The creases also have sidewalls such as 24. The discussion will refer to such a configuration as a ‘stepped’ configuration. FIG. 5 shows another embodiment of ridges and creases. The substrate, when viewed from the side, takes on a shape that imitates a sinusoid waveform and will be referred to here.

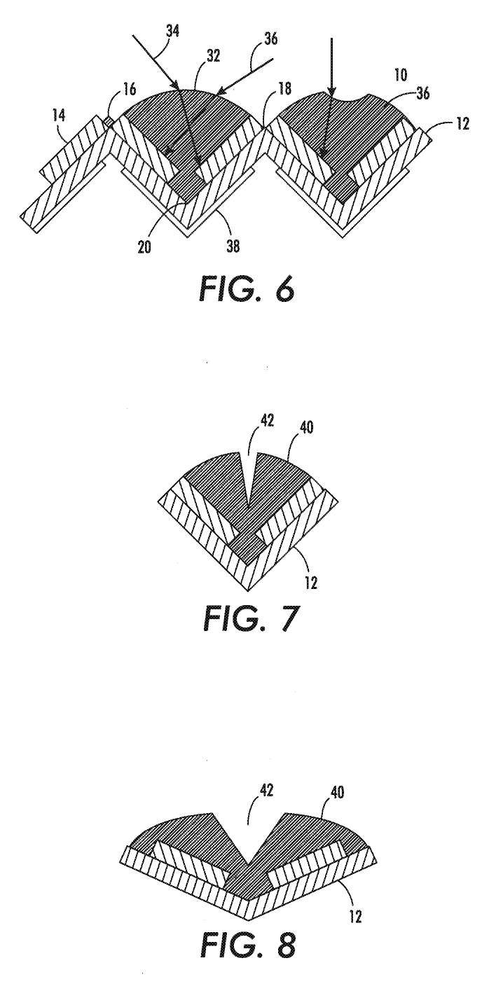

One may employ lenses to increase the effectiveness and efficiency of the functional components, especially in the case of solar tiles, by including lenses in the electronics module. FIG. 6 shows an example of an elastic lens 32 arranged over the functional components such as 16. The lens material may be stamped, molded, printed, laminated or otherwise formed over the components. The surface of the lens may be concave to better direct the light onto the solar tiles.

The lens increases the effectiveness and efficiency of the electronic components because light entering the lens, such as shown by rays 34 and 36, becomes focused on the functional components. To further increase the efficiency of the components, a reflective coating 38 may reside on the surface of the substrate opposite the surface exposed to light, to redirect the light back upwards toward the light source. If the light source has a reflector surrounding it, this light will then reflect back towards the functional components rather than exiting through the substrate unused.

The lens material must have elasticity to allow it to stretch. The lens may consist of an elastomer, silicone, acrylic or urethane, as examples. Alternative, or in addition to, the concavity of the lens shown in FIG. 6, the lens material may easily separate and reattach as it is stretched. FIGS. 7 and 8 show an example of this type of lens. In FIG. 7, the lens 40 has a pre-existing split 42. As the substrate 12 stretches in FIG. 8, the split 42 becomes larger, essentially dividing the lens into two lenses. When the stretching of the substrate ends, the lens will return to the configuration of FIG. 7.

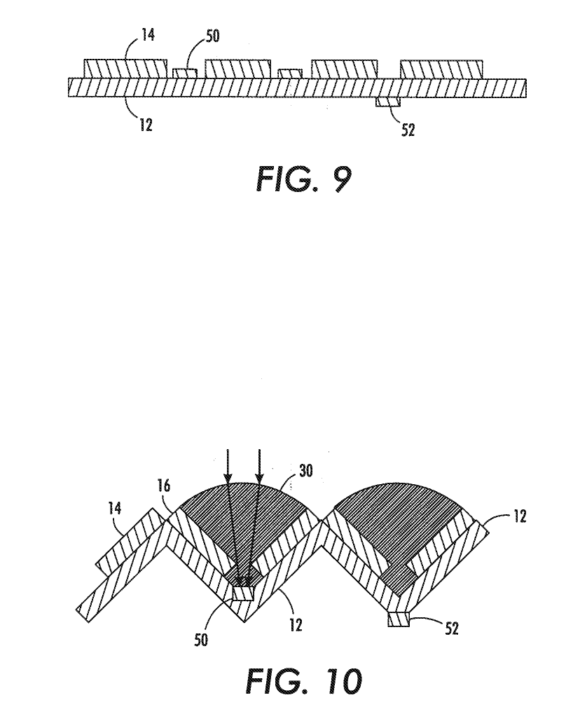

Similar to different configurations for the substrate and the lenses, the electronic components may have different sizes in addition to their different possible functions. FIG. 9 shows functional components 14 and 50 each having different sizes. The smaller sized components may have different or the same function as the larger components. Also, in this embodiment, a smaller sized component 52 resides on a bottom surface of the substrate, where the other functional components reside on a top surface.

One possible implementation of the smaller size components arranges the smaller components such that they reside in the creases, as shown in FIG. 10. In this embodiment, the functional component 50 resides at the bottom of a crease and can employ light that comes through the lens. It may also consist of a component that can redirect light back towards the surface. The functional component 50 may also consist of a light source, such as a light-emitting diode, to generate light towards the lens. They may consist of light scattering structures such as gratings or mirrors.

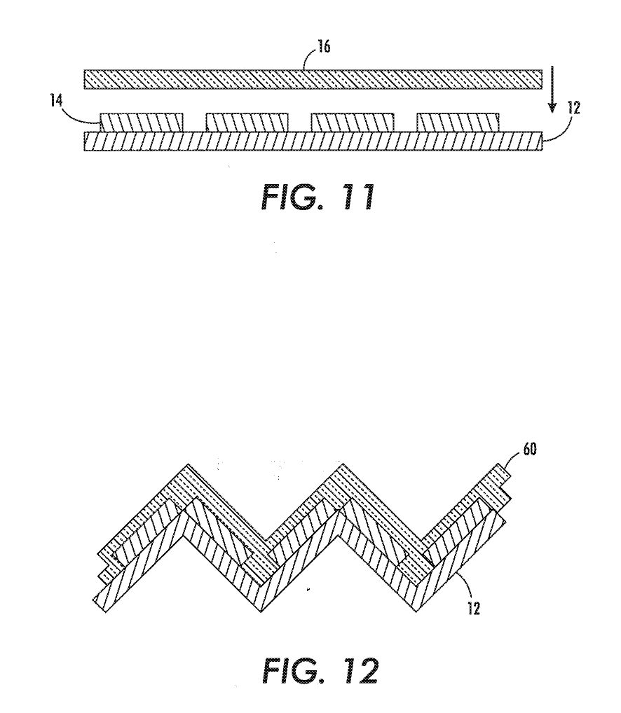

In addition to a stretchy substrate, one may employ an encapsulating layer as shown in FIG. 11. The encapsulation may be applied by a coating step such as dip coating, spray coating or lamination. For example, a dip-coated fluorocarbon coating such as Cytop (Asahi Glass) or dip-coated silicone materials such as 1-2577 conformal coating from Dow Corning may be used. It may also be evaporated such as in the case of evaporated Parylene. Laminated encapsulation materials may include moisture barrier materials such as the Scotchpak series from 3M Corporation. The encapsulation material may be transparent to light where it is required, such as in the case of the functional elements being photosensors, solar cells or light emitting of display devices.

The encapsulant layer 60 bonds or adheres to the functional components such as 14 and the substrate 12, if exposed between the components. If the substrate 12 stretches flat prior to application of the encapsulant layer 60, one may need to stretch the encapsulant layer as well. When released, the substrate and the encapsulant layer would then relax and assume the ridges and creases form discussed above and shown in FIG. 12. The encapsulant layer 60 may also be formed on the surface of a substrate having a pre-existing wavy form as well, and may be used with any configuration of the wavy substrate with no limitation to any particular configuration.

It will be appreciated that several of the above-disclosed and other features and functions, or alternatives thereof, may be desirably combined into many other different systems or applications. Also that various presently unforeseen or unanticipated alternatives, modifications, variations, or improvements therein may be subsequently made by those skilled in the art which are also intended to be encompassed by the following claims.

What is claimed is:

1. An electronics module, comprising:
a wavy substrate having ridges and creases; and
an array of functional components on the substrate, the functional components including solar components and arranged on the substrate so at least one of the components lays between the creases.

2. The electronics module of claim 1, wherein the ridges and creases have one of a waved, sinusoidal or stepped arrangement.

3. The electronics module of claim 1, wherein the substrate is one of a polymer, an elastomer, or a flexible, woven fabric.

4. The electronics module of claim 1, wherein the functional components include at least one of a mirror, a light emitter, a light scattering component, and a sensor.

5. The electronics module of claim 1, wherein at least one functional component is of a different size than others of the functional components.

6. The electronics module of claim 1, further comprising a lens formed over at least one of the functional components.

7. The electronics module of claim 6, wherein the lens is one of an elastomer, silicone, acrylic or urethane.

8. The electronics module of claim 6, wherein components smaller than the components arranged between the creases are arranged in the creases.

9. The electronics module of claim 8, wherein the smaller components comprise one of mirror or light scattering components.

10. The electronics module of claim 1, further comprising a layer of encapsulant arranged over the functional components.

11. The electronics module of claim 10, wherein the layer of encapsulant comprises a layer of one of fluorocarbon, silicone, Parylene, moisture barrier materials, or transparent materials.

12. The electronics module of claim 1, further comprising interconnections between the functional components, where the interconnections are arranged to minimize shading loss for the solar components.

13. A method of manufacturing an electronics module, comprising:
providing functional components, at least one of the functional components being a portion of a solar cell;
mounting the functional components on a flexible substrate; and
forming creases and ridges in the flexible substrate, such that the functional components are arranged to reside between the creases.

14. The method of claim 13, wherein providing the functional components comprises dicing a solar cell to produce solar tiles as functional components.

15. The method of claim 13, wherein providing the functional components comprises providing at least one of a mirror, a light emitter, a light scattering component, and a sensor.

16. The method of claim 13, wherein mounting the functional components comprises one of mounting the functional components on pre-existing interconnections or mounting the functional components and then forming interconnections between the functional components.

17. The method of claim 13, further comprising mounting small components in the creases, wherein the small components have a size less than the functional components.

18. The method of claim 17, wherein the small components include at least one of a mirror or a light scattering component.

19. The method of claim 13, further comprising forming a lens over at least one of the functional components.

20. The method of claim 19, wherein forming a lens comprises one of molding, printing or laminating the lens over the functional component.

21. The method of claim 13, wherein forming creases and ridges comprises stretching the substrate, attaching the components and then releasing the substrate to relax into a wavy state.
